(19) United States
(12) Patent Application Publication
(10) Pub. No.: US 2026/0013220 A1
(43) Pub. Date: Jan. 8, 2026

(54) SEMICONDUCTOR DEVICE

(71) Applicant: Samsung Electronics Co., Ltd., Suwon-si (KR)

(72) Inventors: Byungho Moon, Suwon-si (KR); Donghoon Hwang, Suwon-si (KR); Minwoo Kim, Suwon-si (KR); Jina Kim, Suwon-si (KR)

(21) Appl. No.: 19/014,439

(22) Filed: Jan. 9, 2025

(30) Foreign Application Priority Data
Jul. 3, 2024 (KR) 10-2024-0087248

(51) Int. Cl. H10D 84/85; H10D 84/01

(52) U.S. Cl. CPC H10D 84/856; H10D 84/0186; H10D 84/851

(57) ABSTRACT

A semiconductor device may include, a first substrate, a first active pattern on the first substrate and extending in a first direction, a first gate electrode on the first active pattern and extending in a second direction different from the first direction, a gate capping pattern on the first gate electrode, a gate contact extending into the gate capping pattern and electrically connected to the first gate electrode, a bonding layer on the gate capping pattern, a second substrate on the bonding layer, a second active pattern on the second substrate, wherein the second active pattern comprises a lower pattern and a sheet pattern on the lower pattern, a second gate electrode on the second active pattern and a connection via on the gate contact and electrically connected to each of the gate contact and the second gate electrode, wherein the connection via extends into the second substrate.

### CROSS-REFERENCE TO RELATED APPLICATION

This application claims priority to Korean Patent Application No. 10-2024-0087248, filed in the Korean Intellectual Property Office on Jul. 3, 2024, the entire contents of which are hereby incorporated by reference.

### TECHNICAL FIELD

The present disclosure relates to a semiconductor device.

### BACKGROUND

A semiconductor device is a core component used to control or amplify an electrical signal in an electronic device, and various types of semiconductor devices may be manufactured. For example, memory devices may be used primarily to store and retrieve data, while non-memory devices may be used to control or amplify electrical signals. The semiconductor device is a core component of an electronic device and plays an important role in various fields including computers, communication equipment, consumer electronics, etc.

With the development of industry, the performance and function requirements of the electronic devices are increasing. Accordingly high-performance characteristics of the semiconductor devices are essentially required, and the integration density of the semiconductor devices is increasing to meet these requirements. Various methods for forming semiconductor devices having excellent performance and improved integration density are being studied.

### SUMMARY

In order to solve one or more problems (e.g., the problems described above and/or other problems not explicitly described herein), the present disclosure provides a semiconductor device with improved electrical characteristics and reliability.

According to some embodiments of the present disclosure, by forming the gate contact and the connection via between the first gate electrode and the second gate electrode, the integration density of the semiconductor device can be improved.

According to some embodiments of the present disclosure, by forming the connection via on the lower surface of the second gate electrode, the reliability of the semiconductor device can be improved.

According to some embodiments of the present disclosure, a semiconductor device including, a first substrate, a first active pattern on the first substrate and extending in a first direction, a first gate electrode on the first active pattern and extending in a second direction different from the first direction, a gate capping pattern on the first gate electrode, a gate contact extending into the gate capping pattern and electrically connected to the first gate electrode, a bonding layer on the gate capping pattern, a second substrate on the bonding layer, a second active pattern on the second substrate and extending in the first direction, wherein the second active pattern comprises a lower pattern and a sheet pattern on the lower pattern, a second gate electrode on the second active pattern and extending in the second direction and a connection via on the gate contact and electrically connected to each of the gate contact and the second gate electrode, wherein the connection via extends into the second substrate.

According to some embodiments of the present disclosure, a semiconductor device including, a first substrate, a first active pattern on the first substrate and extending in a first direction, a first gate electrode on the first active pattern and extending in a second direction different from the first direction, a first gate isolation structure on a sidewall of the first gate electrode and extending in the first direction, a gate contact on the first gate electrode, a second substrate on the gate contact, a second active pattern on the second substrate and extending in the first direction, wherein the second active pattern comprises a lower pattern and a sheet pattern on the lower pattern, a second gate electrode on the second active pattern and extending in the second direction, a connection via on the gate contact and electrically connected to each of the gate contact and the second gate electrode and a second gate isolation structure on a sidewall of the second gate electrode and extending in the first direction, wherein the connection via is spaced apart from the lower pattern in the second direction.

According to some embodiments of the present disclosure, a semiconductor device including, a first substrate, a first active pattern on the first substrate and extending in a first direction, wherein the first active pattern comprises a first lower pattern and a first sheet pattern on the first lower pattern, a first gate electrode on the first active pattern and extending in a second direction different from the first direction, a gate capping pattern on the first gate electrode, a first gate isolation structure that extends into the gate capping pattern and the first gate electrode, and extends in the first direction, an interlayer insulating film, a contact etching stop film, and a bonding layer on the gate capping pattern, a gate contact on the first gate electrode and extending into the gate capping pattern and the interlayer insulating film, a second substrate on the bonding layer, a second active pattern on the second substrate and extending in the first direction, wherein the second active pattern comprises a second lower pattern and a second sheet pattern on the second lower pattern, a second gate electrode on the second active pattern and extending in the second direction, a connection via on the gate contact and electrically connected to each of the gate contact and the second gate electrode and a second gate isolation structure on a sidewall of the second gate electrode and extending in the first direction, wherein the connection via extends into the second substrate, and the connection via is spaced apart from the second lower pattern in the second direction.

### BRIEF DESCRIPTION OF THE DRAWINGS

The above and other embodiments and features of the present disclosure will become more apparent by describing in detail example embodiments thereof with reference to the attached drawings, in which:

FIG. 1 is an example plan view provided to explain a semiconductor device according to some embodiments;

FIG. 2 is a cross-sectional view taken along line A-A of FIG. 1;

FIG. 3 is a cross-sectional view taken along line B-B of FIG. 1;

FIG. 4 is an enlarged view provided to explain a region Q1 of FIG. 3;

FIG. 5 is a diagram provided to explain a semiconductor device according to some embodiments;

FIG. 6 is a diagram provided to explain a semiconductor device according to some embodiments;

FIG. 7 is a diagram provided to explain a semiconductor device according to some embodiments;

FIGS. 8 to 10 are diagrams provided to explain a semiconductor device according to some embodiments;

FIGS. 11 to 28 are diagrams illustrating intermediate stages, which are provided to explain a method for manufacturing a semiconductor device according to some embodiments.

### DETAILED DESCRIPTION

Hereinafter, a semiconductor device and a method for manufacturing the same according to some embodiments of the present disclosure will be described in detail with reference to the drawings. Herein, the terms indicating order, such as first, second, etc., are used to distinguish elements having the same/similar functions, and the ordinal numbers may be interchanged according to the order in which the terms are mentioned. To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection.

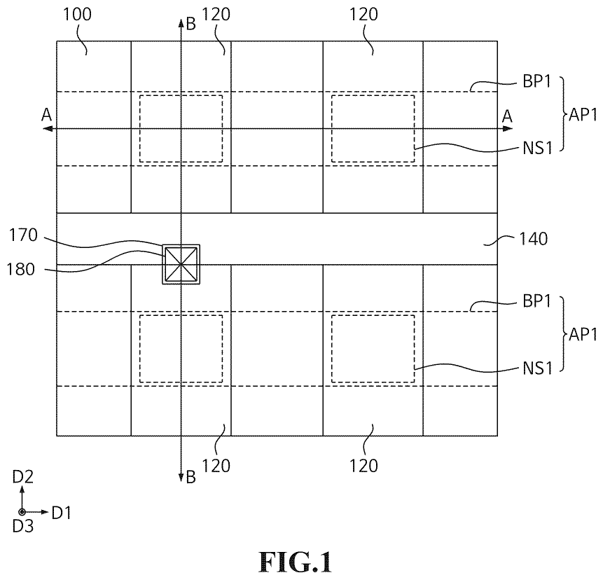

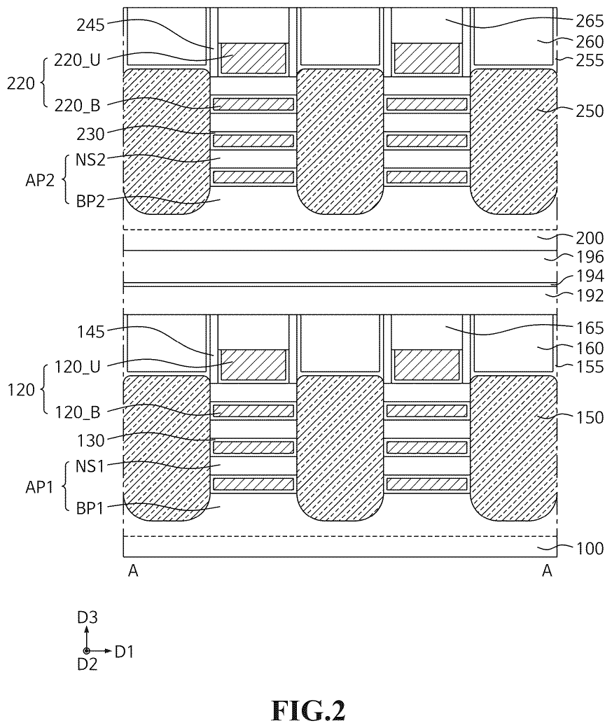

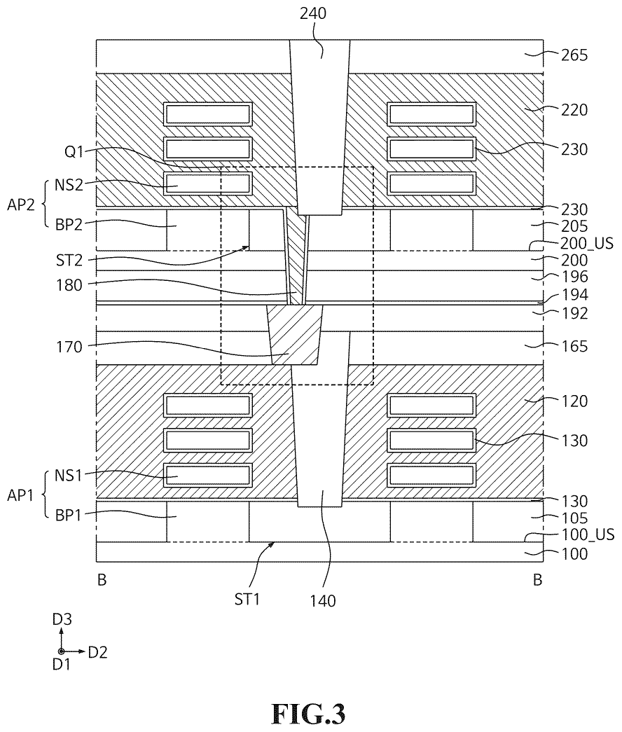

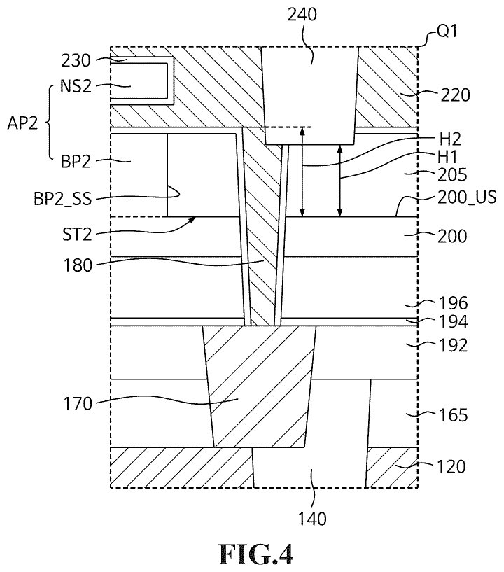

FIG. 1 is an example plan view provided to explain a semiconductor device according to some embodiments. FIG. 2 is a cross-sectional view taken along line A-A of FIG. 1. FIG. 3 is a cross-sectional view taken along line B-B of FIG. 1. FIG. 4 is an enlarged view provided to explain a region Q1 of FIG. 3. For reference, configurations other than a first substrate 100, a first active pattern AP1, a first gate electrode 120, a first gate isolation structure 140, a gate contact 170, and a connection via 180 are omitted in FIG. 1.

Referring to FIGS. 1 to 4, the semiconductor device according to some embodiments may include the first substrate 100, a second substrate 200, the first active pattern AP1, a second active pattern AP2, the first gate electrode 120, a second gate electrode 220, the first gate isolation structure 140, a second gate isolation structure 240, a first gate capping pattern 165, a second gate capping pattern 265, a gate contact 170, the connection via 180, a bonding layer 196, etc.

The semiconductor device according to some embodiments may include a MOSFET, and more specifically, may include a gate-all-round (GAA) transistor and a three-dimensional multi-stack semiconductor device referred to as a multi-bridge channel FET (MBCFET).

The first substrate 100 may be a bulk silicon or a silicon-on-insulator (SOI). On the other hand, the first substrate 100 may include silicon germanium (SiGe), silicon germanium on insulator (SGOI), indium antimony, lead tellurium compound, indium arsenic, indium phosphide, gallium arsenic, or gallium antimony, but is not limited thereto.

The first active pattern AP1 may be disposed on the first substrate 100. The first active pattern AP1 may extend in a first direction D1. The first active pattern AP1 may be disposed to be spaced apart from the adjacent first active pattern AP1 in a second direction D2. In this case, the first direction D1 is a direction intersecting the second direction D2. Each of the first and second directions D1 and D2 may be a direction parallel to an upper surface 100_US of the first substrate 100.

The first active pattern AP1 may be a multi-channel active pattern. The first active pattern AP1 may include a first lower pattern BP1 and a plurality of first sheet patterns NS1.

The first lower pattern BP1 may protrude from the first substrate 100. The first lower pattern BP1 may extend in the first direction D1. The first lower pattern BP1 may be disposed to be spaced apart from the adjacent first lower pattern BP1 in the second direction D2. The first lower pattern BP1 and the adjacent first lower pattern BP1 may be isolated by a first device isolation trench ST1. The first device isolation trench ST1 may be defined by the upper surface 100_US of the first substrate 100 and the side surfaces of the first lower patterns BP1.

The plurality of first sheet patterns NS1 may be disposed on the first lower pattern BP1. The plurality of first sheet patterns NS1 may be spaced apart from the first lower pattern BP1 in a third direction D3. Each of the first sheet patterns NS1 may be spaced apart from each other in the third direction D3. The third direction D3 may be a direction intersecting each of the first and second directions D1 and D2. The third direction D3 may be a direction perpendicular to the upper surface 100_US of the first substrate 100. The third direction D3 may be a thickness direction of the first substrate 100. The first sheet pattern NS1 may have a nanosheet shape, such as a pattern that extends in the first direction D1 and is surrounded by the first gate electrode 120 in the plane of the second direction D2 and the third direction D3. Although it is illustrated that there are three first sheet patterns NS1, embodiments are not limited thereto.

The first lower pattern BP1 may be formed by etching a portion of the first substrate 100. However, embodiments are not limited thereto. For example, the first lower pattern BP1 may include an epitaxial layer grown from the first substrate 100. The first lower pattern BP1 may include an element semiconductor material such as silicon (Si) or germanium (Ge). In addition, the first lower pattern BP1 may include a compound semiconductor. For example, the first lower pattern BP1 may include a group IV-IV compound semiconductor or a group III-V compound semiconductor.

For example, the group IV-IV compound semiconductor may be a binary compound or a ternary compound including at least two or more of carbon (C), silicon (Si), germanium (Ge), and/or tin (Sn).

For example, the group III-V compound semiconductor may be one of a binary compound, a ternary compound, or a quaternary compound formed by a combination of at least one of aluminum (Al) or gallium (Ga), and/or indium (In) as a group III element and one of phosphorus (P), arsenic (As), and/or antimony (Sb) as a group V element.

The first sheet pattern NS1 may include one of an elemental semiconductor material such as silicon (Si), silicon germanium (SiGe), a group IV-IV compound semiconductor, or a group III-V compound semiconductor. The first sheet pattern NS1 may include the same material as the first lower pattern BP1 or may include a different material from the first lower pattern BP1.

The first lower pattern BP1 and the plurality of first sheet patterns NS1 may include silicon (Si). In other embodiments, the first lower pattern BP1 and the plurality of first sheet patterns NS1 may include silicon germanium (SiGe). In other embodiments, the first lower pattern BP1 may include silicon (Si), and the plurality of first sheet patterns NS1 may include silicon germanium (SiGe).

A first field insulating film 105 may be disposed on the first substrate 100. The first field insulating film 105 may fill at least a portion of the first device isolation trench ST1. The first field insulating film 105 may be disposed between the adjacent first lower patterns BP1. The first field insulating film 105 may extend in the first direction D1. The first field insulating film 105 may be formed on the upper surface 100_US of the first substrate 100. The first field insulating film 105 may cover, overlap, or be on a side surface of the first lower pattern BP1. For example, the first field insulating film 105 may cover, overlap, or be on the side surface of the first lower pattern BP1, but may not be disposed on an upper surface of the first lower pattern BP1.

For example, the first field insulating film 105 may include oxide, nitride, nitride oxide, or a combination thereof. Although it is illustrated that the first field insulating film 105 is a single film, it is only for convenience of description, and embodiments are not limited thereto. For example, the first field insulating film 105 may be formed of a plurality of films.

A first source/drain pattern 150 may be disposed on the first active pattern AP1. The first source/drain pattern 150 may be disposed on the first lower pattern BP1. The first source/drain pattern 150 may be connected to the first sheet pattern NS1. Aa portion of a side surface of the first source/drain pattern 150 may be in contact with the first sheet pattern NS1. Another portion of the side surface of the first source/drain pattern 150 may be in contact with a first gate insulating film 130. The first source/drain pattern 150 may connect the first sheet patterns NS1 spaced apart from each other in the first direction D1. The first source/drain pattern 150 may be disposed between the first sheet patterns NS1 spaced apart from each other in the first direction D1.

The first source/drain pattern 150 may be disposed on at least one side of the first gate electrode 120. The first source/drain pattern 150 may be disposed between the first gate electrodes 120 adjacent to each other in the first direction D1. Unlike the illustration, the first source/drain pattern 150 may be disposed on one side of the first gate electrode 120 and may not be disposed on the other side of the first gate electrode 120.

The first source/drain pattern 150 may be an epitaxial pattern formed by a selective epitaxial growth process using the first active pattern AP1 as a seed. The first source/drain pattern 150 may serve as a source/drain of a transistor that uses the first sheet pattern NS1 as a channel region.

The first source/drain pattern 150 may include a semiconductor material. For example, the first source/drain pattern 150 may include an element semiconductor material such as silicon (Si) or germanium (Ge). In addition, for example, the first source/drain pattern 150 may include a binary compound or a ternary compound including at least two or more of carbon (C), silicon (Si), germanium (Ge), or tin (Sn), or a compound doped with a group IV element. For example, the first source/drain pattern 150 may include silicon (Si), silicon-germanium (SiGe), germanium (Ge), silicon carbide (SiC), etc., but is not limited thereto.

The first source/drain pattern 150 may include impurities doped into a semiconductor material. The doped impurities may include at least one of boron (B), phosphorus (P), carbon (C), arsenic (As), antimony (Sb), bismuth (Bi), or oxygen (O), but embodiments are not limited thereto.

Although it is illustrated that the first source/drain pattern 150 is a single film, it is only for convenience of description, and embodiments are not limited thereto. The first source/drain pattern 150 may include a plurality of films including different materials. In other embodiments, the first source/drain pattern 150 may include the same material and may include a plurality of layers having different concentrations of constituent materials.

Although not illustrated, the semiconductor device according to some embodiments may further include a lower source/drain contact. The lower source/drain contact may be disposed on the first source/drain pattern 150. The lower source/drain contact may penetrate or extend into a first interlayer insulating film 160 and a first etching stop film 155 and be connected to the first source/drain pattern 150. In other embodiments, the lower source/drain contact may penetrate or extend into the first substrate 100 and be electrically connected to the first source/drain pattern 150.

The first gate electrode 120 may extend on the first substrate 100 in the second direction D2. The first gate electrode 120 may intersect the first active pattern AP1. The first gate electrode 120 may be disposed on the first lower pattern BP1. The first gate electrode 120 may be disposed to be spaced apart from the adjacent first gate electrode 120 in the first direction D1. The first gate electrode 120 may surround the plurality of first sheet patterns NS1. The first gate electrode 120 may surround four surfaces of the first sheet pattern NS1. For example, the first gate electrode 120 may surround an upper surface, a lower surface, and both side surfaces of the first sheet pattern NS1. The upper and lower surfaces of the first sheet pattern NS1 may refer to surfaces intersecting the third direction D3, and both side surfaces of the first sheet pattern NS1 may refer to surfaces intersecting the second direction D2.

The first gate electrode 120 may include a first upper gate electrode 120_U and a first lower gate electrode 120_B. The first lower gate electrode 120_B may be disposed between the first sheet patterns NS1 adjacent to each other in the third direction D3. The first lower gate electrode 120_B may be disposed between the plurality of first sheet patterns NS1, and may be disposed between the first lower pattern BP1 and the first sheet pattern NS1 disposed lowermost among the plurality of first sheet patterns NS1. The first upper gate electrode 120_U may be disposed on the first sheet pattern NS1 disposed uppermost among the plurality of first sheet patterns NS1.

In some embodiments, the first active pattern AP1 may include the plurality of first sheet patterns NS1, and the first gate electrode 120 may include a plurality of first lower gate electrodes 120_B. In this case, the number of the first lower gate electrodes 120_B may be proportional to the number of the first sheet patterns NS1 included in the first active pattern AP1. The number of the first lower gate electrodes 120_B may be the same as the number of the first sheet patterns NS1. For example, as illustrated in FIG. 2, the number of the first lower gate electrodes 120_B may be three, which is the same as the number of the first sheet patterns NS1. However, embodiments are not limited thereto.

The first gate electrode 120 may include at least one of a metal, a metal alloy, a conductive metal nitride, a metal silicide, a doped semiconductor material, a conductive metal oxide, or a conductive metal oxynitride. For example, the first gate electrode 120 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or a combination thereof, but is not limited thereto. The conductive metal oxide and the conductive metal oxynitride may include an oxidized form of the material described above, but is not limited thereto.

The first gate isolation structure 140 may penetrate or extend into the first gate capping pattern 165 and the first gate electrode 120. The first gate isolation structure 140 may extend in the first and third directions D1 and D3. The first gate electrode 120 may be isolated in the second direction D2 by the first gate isolation structure 140. A lower portion of the first gate isolation structure 140 may penetrate or extend into an upper surface of the first field insulating film 105. A lower surface of the first gate isolation structure 140 may be disposed in the first field insulating film 105. The lower surface of the first gate isolation structure 140 may be in contact with the first field insulating film 105.

In some embodiments, the first gate isolation structure 140 may have a tapered shape. That is, a width of the first gate isolation structure 140 in the second direction D2 may decrease toward the first substrate 100. However, embodiments are not limited to the above. For example, unlike the illustration, the width of the first gate isolation structure 140 may be constant.

The first gate insulating film 130 may be disposed between the first gate electrode 120 and the plurality of first sheet patterns NS1, between the first gate electrode 120 and the first lower pattern BP1, and between the first gate electrode 120 and the first source/drain pattern 150. Specifically, the first gate insulating film 130 may be disposed between the first upper gate electrode 120_U and the first sheet pattern NS1 disposed uppermost among the plurality of first sheet patterns NS1. The first gate insulating film 130 may be disposed between the first lower gate electrode 120_B and the first sheet pattern NS1. The first gate insulating film 130 may surround the first sheet pattern NS1. The first gate insulating film 130 may extend in the first direction D1 along the upper and lower surfaces of the first sheet pattern NS1.

In some embodiments, the first gate insulating film 130 may include a plurality of films. For example, the first gate insulating film 130 may include a first interfacial insulating film and a first high-k insulating film. For example, the first interfacial insulating film may include silicon oxide. The first high-k insulating film may include a high-k material having a dielectric constant greater than that of the first interfacial insulating film. For example, the first high-k insulating film may include at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

A first gate spacer 145 may be disposed on side surfaces of the first upper gate electrode 120_U and the first gate capping pattern 165. For example, the first gate spacer 145 may extend along the side surface of the first upper gate electrode 120_U and a side surface of the first gate capping pattern 165. The first gate spacer 145 may not be positioned between the first lower pattern BP1 and the first sheet pattern NS1. The first gate spacer 145 may not be positioned between the first sheet patterns NS1 adjacent to each other in the third direction D3.

For example, the first gate spacer 145 may include at least one of silicon nitride (SiN), silicon nitride oxide (SiON), silicon oxide (SiO₂), silicon carbonate (SiOCN), silicon boron nitride (SiBN), silicon boron oxide (SiOBN), silicon oxycarbide (SiOC), or a combination thereof. Although it is illustrated that the first gate spacer 145 is a single film, it is only for convenience of description, and embodiments are not limited thereto.

The first gate capping pattern 165 may be disposed on the first upper gate electrode 120_U. The first gate capping pattern 165 may cover, overlap, or be on an upper surface of the first upper gate electrode 120_U. The first gate capping pattern 165 may overlap or be on the first upper gate electrode 120_U in the third direction D3. The first gate capping pattern 165 may be disposed between the first gate spacers 145. The side surface of the first gate capping pattern 165 may be in contact with the first gate spacer 145. An upper surface of the first gate capping pattern 165 may be disposed on the same plane as an upper surface of the first interlayer insulating film 160. However, embodiments are not limited thereto.

Although it is illustrated that the first gate capping pattern 165 is disposed between the first gate spacers 145, embodiments are not limited thereto. For example, the side surface of the first gate capping pattern 165 may be in contact with the first etching stop film 155. In this case, the first gate capping pattern 165 may be disposed on the upper surface of the first upper gate electrode 120_U and an upper surface of the first gate spacer 145.

For example, the first gate capping pattern 165 may include at least one of silicon nitride (SiN), silicon oxynitride (SiON), silicon carbon nitride (SiCN), silicon oxycarbonitride (SiOCN), or a combination thereof. The first gate capping pattern 165 may include a material having etch selectivity with respect to the first interlayer insulating film 160.

The first etching stop film 155 may extend along a profile of a side surface of the first gate spacer 145 and an upper surface of the first source/drain pattern 150. Although not illustrated, the first etching stop film 155 may be disposed on the upper surface of the first field insulating film 105.

The first etching stop film 155 may include a material having etching selectivity with respect to the first interlayer insulating film 160. For example, the first etching stop film 155 may include at least one of silicon nitride (SiN), silicon oxide (SiO), silicon oxynitride (SiON), silicon oxycarbonitride (SiOCN), silicon boron nitride (SiBN), silicon oxyboron nitride (SiOBN), silicon oxycarbide (SiOC), or a combination thereof.

The first interlayer insulating film 160 may be disposed on the first etching stop film 155. The first interlayer insulating film 160 may be disposed on the first source/drain pattern 150. The first interlayer insulating film 160 may be disposed on one side of the first upper gate electrode 120_U. The first interlayer insulating film 160 may be disposed between the first upper gate electrodes 120_U.

For example, the first interlayer insulating film 160 may include at least one of silicon oxide (SiO), silicon nitride (SiN), silicon oxynitride (SiON), or a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but is not limited thereto.

A second interlayer insulating film 192 may be disposed on the first gate capping pattern 165. The second interlayer insulating film 192 may extend along the upper surface of the first gate capping pattern 165. The second interlayer insulating film 192 may include an insulating material. The description of the material of the second interlayer insulating film 192 may be the same as the description of the material of the first interlayer insulating film 160. For example, the second interlayer insulating film 192 may include silicon oxide (SiO).

The gate contact 170 may be disposed on the first gate electrode 120. The gate contact 170 may penetrate or extend into the second interlayer insulating film 192 and the first gate capping pattern 165 and be disposed on an upper surface of the first gate electrode 120. The gate contact 170 may be connected to the first gate electrode 120. In some embodiments, an upper surface of the gate contact 170 may be disposed on the same plane as an upper surface of the second interlayer insulating film 192.

The gate contact 170 may be disposed to be spaced apart from the first active pattern AP1 in the second direction D2. In other words, the gate contact 170 may not overlap the first active pattern AP1 in the third direction D3. However, embodiments are not limited to the above. For example, a portion of the gate contact 170 may overlap at least a portion of the first active pattern AP1 in the third direction D3.

In some embodiments, the gate contact 170 may be disposed on the first gate isolation structure 140. The gate contact 170 may overlap the first gate isolation structure 140 in the third direction D3. The gate contact 170 may be in contact with the first gate isolation structure 140. A portion of the first gate isolation structure 140 may be recessed corresponding to the shape of the gate contact 170.

The gate contact 170 may include a conductive material. The gate contact 170 may include at least one of ruthenium (Ru), cobalt (Co), nickel (Ni), nickel boron (NiB), tungsten (W), tungsten nitride (WN), zirconium (Zr), zirconium nitride (ZrN), vanadium (V), vanadium nitride (VN), niobium (Nb), niobium nitride (NbN), platinum (Pt) iridium (Ir), rhodium (Rh), a two-dimensional material (2D material), aluminum (Al), copper (Cu), tungsten (W), cobalt (Co), ruthenium (Ru), silver (Ag), gold (Au), manganese (Mn), or molybdenum (Mo).

A second etching stop film 194 may be disposed on the second interlayer insulating film 192. The bonding layer 196 may be disposed on the second etching stop film 194. That is, the second interlayer insulating film 192, the second etching stop film 194, and the bonding layer 196 may be sequentially stacked on the first gate capping pattern 165.

The description of the material of the second etching stop film 194 may be the same as the description of the material of the first etching stop film 155. For example, the bonding layer 196 may include at least one of silicon oxide (SiO), silicon nitride (SiN), silicon oxynitride (SiON), silicon oxycarbonitride (SiOCN), silicon boron nitride (SiBN), silicon boron oxynitride (SiOBN), silicon oxycarbon (SiOC), or a combination thereof.

The second substrate 200 may be disposed on the bonding layer 196. The second substrate 200 may be bulk silicon or SOI. On the other hand, the second substrate 200 may include silicon germanium (SiGe), SGOI, indium antimony, lead tellurium compound, indium arsenic, indium phosphide, gallium arsenic, or gallium antimony, but is not limited thereto.

The second active pattern AP2 may be disposed on the second substrate 200. The second active pattern AP2 may extend in the first direction D1. The second active pattern AP2 may be disposed on the first active pattern AP1. The second active pattern AP2 may overlap the first active pattern AP1 in the third direction D3.

The first active pattern AP1 may be a region in which a PMOS is formed, and the second active pattern AP2 may be a region in which an NMOS is formed. In other embodiments, the first active pattern AP1 may be a region in which an NMOS is formed, and the second active pattern AP2 may be a region in which a PMOS is formed.

The second active pattern AP2 may be a multi-channel active pattern. The second active pattern AP2 may include a second lower pattern BP2 and a plurality of second sheet patterns NS2.

The second lower pattern BP2 may protrude from the second substrate 200. The second lower pattern BP2 may extend in the first direction D1. The second lower pattern BP2 may be disposed to be spaced apart from the adjacent second lower pattern BP2 in the second direction D2. The second lower pattern BP2 adjacent to the second lower pattern BP2 may be isolated by a second device isolation trench ST2. The second device isolation trench ST2 may be defined by an upper surface 200_US of the second substrate 200 and side surfaces BP2_SS of the second lower patterns BP2.

The plurality of second sheet patterns NS2 may be disposed on the second lower pattern BP2. The plurality of second sheet patterns NS2 may be spaced apart from the second lower pattern BP2 in the third direction D3. The second sheet patterns NS2 may be spaced apart from each other in the third direction D3. The second sheet pattern NS2 may have a nanosheet shape. Although it is illustrated that there are three first sheet patterns NS1, embodiments are not limited thereto.

The description of the material of the second lower pattern BP2 and the second sheet pattern NS2 may be the same as the description of the material of each of the first lower pattern BP1 and the first sheet pattern NS1.

A second field insulating film 205 may be disposed on the second substrate 200. The second field insulating film 205 may fill at least a portion of the second device isolation trench ST2. The second field insulating film 205 may be disposed between the adjacent second lower patterns BP2. The second field insulating film 205 may extend in the first direction D1. The second field insulating film 205 may be formed on the upper surface of the second substrate 200. The second field insulating film 205 may cover or be on a side surface of the second lower pattern BP2. For example, the second field insulating film 205 may cover or be on the side surface of the second lower pattern BP2, but may not be disposed on an upper surface of the second lower pattern BP2.

The second gate electrode 220 may extend on the second substrate 200 in the second direction D2. The second gate electrode 220 may intersect the second active pattern AP2. The second gate electrode 220 may be disposed on the second lower pattern BP2. The second gate electrode 220 may be disposed to be spaced apart from the adjacent second gate electrode 220 in the first direction D1. The second gate electrode 220 may surround the plurality of second sheet patterns NS2. The second gate electrode 220 may surround or extend around four surfaces of the second sheet pattern NS2. For example, the second gate electrode 220 may surround or extend around an upper surface, a lower surface, and both side surfaces of the second sheet pattern NS2. The upper and lower surfaces of the second sheet pattern NS2 may refer to surfaces intersecting the third direction D3, and both side surfaces of the second sheet pattern NS2 may refer to surfaces intersecting the second direction D2.

The second gate electrode 220 may include a second upper gate electrode 220_U and a second lower gate electrode 220_B. The second lower gate electrode 220_B may be disposed between the second sheet patterns NS2 adjacent to each other in the third direction D3. The second lower gate electrode 220_B may be disposed between the plurality of second sheet patterns NS2, and may be disposed between the second lower pattern BP2 and the second sheet pattern NS2 disposed lowermost among the plurality of second sheet patterns NS2. The second upper gate electrode 220_U may be disposed on the second sheet pattern NS2 disposed uppermost among the plurality of second sheet patterns NS2.

In some embodiments, the second active pattern AP2 may include the plurality of second sheet patterns NS2, and the second gate electrode 220 may include a plurality of second lower gate electrodes 220_B. In this case, the number of the second lower gate electrodes 220_B may be proportional to the number of the second sheet patterns NS2 included in the second active pattern AP2. The number of the second lower gate electrodes 220_B may be the same as the number of the second sheet patterns NS2. For example, as illustrated in FIG. 2, the number of the second lower gate electrodes 220_B is three, which is the same as the number of the second sheet patterns NS2. However, embodiments are not limited thereto.

The second gate electrode 220 may include at least one of a metal, a metal alloy, a conductive metal nitride, a metal silicide, a doped semiconductor material, a conductive metal oxide, or a conductive metal oxynitride. The description of the material of the second gate electrode 220 may be the same as the description of the material of the first gate electrode 120.

Although it is illustrated that each of the first gate electrode 120 and the second gate electrode 220 is a single film, embodiments are not limited thereto. For example, each of the first gate electrode 120 and the second gate electrode 220 may include a work function control film for adjusting a work function and a filling conductive film for filling a space formed by the work function control film. The work function adjusting film may include, for example, at least one of titanium nitride (TiN), tantalum nitride (TaN), titanium carbide (TiC), tantalum carbide (TaC), titanium aluminum carbide (TiAlC), or a combination thereof. The filling conductive film may include, for example, tungsten (W) or aluminum (Al).

In some embodiments, the work function adjusting film of the first gate electrode 120 and the work function adjusting film of the second gate electrode 220 may include different materials. The work function adjusting film of the first gate electrode 120 may include a P-type work function adjusting film, and the work function adjusting film of the second gate electrode 220 may include an N-type work function adjusting film. In other embodiments, the work function adjusting film of the first gate electrode 120 may include an N-type work function adjusting film, and the work function adjusting film of the second gate electrode 220 may include a P-type work function adjusting film.

The second gate isolation structure 240 may penetrate the second gate capping pattern 265 and the second gate electrode 220. The second gate isolation structure 240 may extend in the first and third directions D1 and D3. The second gate electrode 220 may be isolated in the second direction D2 by the second gate isolation structure 240. A lower portion of the second gate isolation structure 240 may penetrate or extend into an upper surface of the second field insulating film 205. A lower surface of the second gate isolation structure 240 may be disposed in the second field insulating film 205. The lower surface of the second gate isolation structure 240 may be in contact with the second field insulating film 205. In some embodiments, a distance H1 from the upper surface 200_US of the second substrate 200 to the lower surface of the second gate isolation structure 240 may be less than a distance H2 from the upper surface 200_US of the second substrate 200 to an upper surface of the connection via 180.

In some embodiments, the second gate isolation structure 240 may have a tapered shape. That is, a width of the second gate isolation structure 240 in the second direction D2 may decrease toward the second substrate 200. However, embodiments are not limited to the above. For example, unlike the illustration, the width of the second gate isolation structure 240 may be constant.

A second gate insulating film 230 may be disposed between the second gate electrode 220 and the plurality of second sheet patterns NS2, between the second gate electrode 220 and the second lower pattern BP2, and between the second gate electrode 220 and a second source/drain pattern 250. Specifically, the second gate insulating film 230 may be disposed between the second upper gate electrode 220_U and the second sheet pattern NS2 disposed uppermost among the plurality of second sheet patterns NS2. The second gate insulating film 230 may be disposed between the second lower gate electrode 220_B and the second sheet pattern NS2. The second gate insulating film 230 may surround or extend around the second sheet pattern NS2. The second gate insulating film 230 may extend in the first direction D1 along the upper and lower surfaces of the second sheet pattern NS2.

In some embodiments, the second gate insulating film 230 may include a plurality of films. For example, the second gate insulating film 230 may include a second interfacial insulating film and a second high-k insulating film. The description of the materials of the second interfacial insulating film and the second high-k insulating film may be the same as the description of the materials of each of the first interfacial insulating film and the first high-k insulating film.

The connection via 180 may be disposed on the gate contact 170. The connection via 180 may penetrate or extend into the second field insulating film 205, the second substrate 200, the bonding layer 196, and the second etching stop film 194. The connection via 180 may be connected to each of the gate contact 170 and the second gate electrode 220. For example, one end of the connection via 180 may be in contact with the upper surface of the gate contact 170, and the other end of the connection via 180 may be in contact with a lower surface of the second gate electrode 220.

A portion of the connection via 180 may be disposed in the second field insulating film 205. The second field insulating film 205 may surround or extend around a portion of the connection via 180. The connection via 180 may be spaced apart from the second lower pattern BP2 in the second direction D2. The second field insulating film 205 may be disposed between the connection via 180 and the second lower pattern BP2. The connection via 180 may be spaced apart from the second sheet pattern NS2 in the second direction D2. In other words, the connection via 180 may not overlap the second sheet pattern NS2 in the third direction D3.

The second gate insulating film 230 may surround or extend around a side surface of the connection via 180. The second gate insulating film 230 may extend along the side surface of the connection via 180 and may be in contact with the second etching stop film 194 and the gate contact 170. From a cross-sectional point of view, the second gate insulating film 230 may be disposed on both side surfaces of the connection via 180.

In some embodiments, the second gate isolation structure 240 may be disposed on the connection via 180. The connection via 180 may overlap the second gate isolation structure 240 in the third direction D3. The connection via 180 may be in contact with the second gate isolation structure 240. A portion of the connection via 180 may be recessed corresponding to the shape of the second gate isolation structure 240.

The connection via 180 may include a conductive material. The connection via 180 may include a material different from that of the second gate electrode 220. The connection via 180 may include at least one of, for example, molybdenum (Mo), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), a two-dimensional material (2D material), aluminum (Al), copper (Cu), tungsten (W), cobalt (Co), ruthenium (Ru), silver (Ag), gold (Au), or manganese (Mn).

A separate wiring may be necessary to electrically connect the first gate electrode 120 and the second gate electrode 220. For example, a wiring structure connected to a lower portion of the first gate electrode 120 and a wiring structure connected to an upper portion of the second gate electrode 220 may be needed. In some embodiments, the semiconductor device may electrically connect the first gate electrode 120 and the second gate electrode 220 with the gate contact 170 disposed on the upper surface of the first gate electrode 120 and the connection via 180 disposed on the lower surface of the second gate electrode 220. Accordingly, the integration density of the semiconductor device may be improved.

The second gate capping pattern 265 may be disposed on the second upper gate electrode 220_U. The second gate capping pattern 265 may cover, overlap, or be on an upper surface of the second upper gate electrode 220_U. The second gate capping pattern 265 may overlap the second upper gate electrode 220_U in the third direction D3. The second gate capping pattern 265 may be disposed between second gate spacers 245. A side surface of the second gate capping pattern 265 may be in contact with a second gate spacer 245. An upper surface of the second gate capping pattern 265 may be disposed on the same plane as an upper surface of a second interlayer insulating film 260. However, embodiments are not limited thereto.

Although it is illustrated that the second gate capping pattern 265 is disposed between the second gate spacers 245, embodiments are not limited thereto. For example, the side surface of the second gate capping pattern 265 may be in contact with a third etching stop film 255. In this case, the second gate capping pattern 265 may be disposed on the upper surface of the second upper gate electrode 220_U and an upper surface of the second gate spacer 245.

The second gate spacer 245 may be disposed on side surfaces of the second upper gate electrode 220_U and the second gate capping pattern 265. For example, the second gate spacer 245 may extend along the side surface of the second upper gate electrode 220_U and the side surface of the second gate capping pattern 265. The second gate spacer 245 may not be positioned between the second lower pattern BP2 and the second sheet pattern NS2. The second gate spacer 245 may not be positioned between the second sheet patterns NS2 adjacent to each other in the third direction D3.

The description of the material of the second gate capping pattern 265 and the second gate spacer 245 may be the same as the description of the material of each of the first gate capping pattern 165 and the first gate spacer 145.

The second source/drain pattern 250 may be disposed on the second active pattern AP2. The second source/drain pattern 250 may be disposed on the second lower pattern BP2. The second source/drain pattern 250 may be connected to the second sheet pattern NS2. A portion of the side surface of the second source/drain pattern 250 may be in contact with the second sheet pattern NS2. Another portion of the side surface of the second source/drain pattern 250 may be in contact with the second gate insulating film 230. The second source/drain pattern 250 may connect the second sheet patterns NS2 spaced apart from each other in the first direction D1. The second source/drain pattern 250 may be disposed between the second sheet patterns NS2 spaced apart from each other in the first direction D1.

The second source/drain pattern 250 may be disposed on at least one side of the second gate electrode 220. The second source/drain pattern 250 may be disposed between the second gate electrodes 220 adjacent to each other in the first direction D1. Unlike the illustration, the second source/drain pattern 250 may be disposed on one side of the second gate electrode 220 and may not be disposed on the other side of the second gate electrode 220.

The second source/drain pattern 250 may be an epitaxial pattern formed by a selective epitaxial growth process using the second active pattern AP2 as a seed. The second source/drain pattern 250 may serve as a source/drain of a transistor that uses the second sheet pattern NS2 as a channel region.

The second source/drain pattern 250 may include a semiconductor material. The description of the material of the second source/drain pattern 250 may be the same as the description of the material of the first source/drain pattern 150.

Although it is illustrated that the second source/drain pattern 250 is a single film, it is only for convenience of description, and embodiments are not limited thereto. The second source/drain pattern 250 may include a plurality of films including different materials. In other embodiments, the second source/drain pattern 250 may include the same material and may include a plurality of layers having different concentrations of constituent materials.

Although not illustrated, the semiconductor device according to some embodiments may further include an upper source/drain contact. The upper source/drain contact may be disposed on the second source/drain pattern 250. The upper source/drain contact may penetrate or extend into the second interlayer insulating film 260 and the third etching stop film 255 and be connected to the second source/drain pattern 250.

The third etching stop film 255 may extend along a profile of a side surface of the second gate spacer 245 and an upper surface of the second source/drain pattern 250. Although not illustrated, the third etching stop film 255 may be disposed on the upper surface of the second field insulating film 205.

The second interlayer insulating film 260 may be disposed on the third etching stop film 255. The second interlayer insulating film 260 may be disposed on the second source/drain pattern 250. The second interlayer insulating film 260 may be disposed on one side of the second upper gate electrode 220_U. The second interlayer insulating film 260 may be disposed between the second upper gate electrodes 220_U.

The third etching stop film 255 may include a material having etching selectivity with respect to the second interlayer insulating film 260. The description of the material of the third etching stop film 255 may be the same as the description of the material of the first etching stop film 155. The description of the material of the second interlayer insulating film 260 may be the same as the description of the material of the first interlayer insulating film 160.

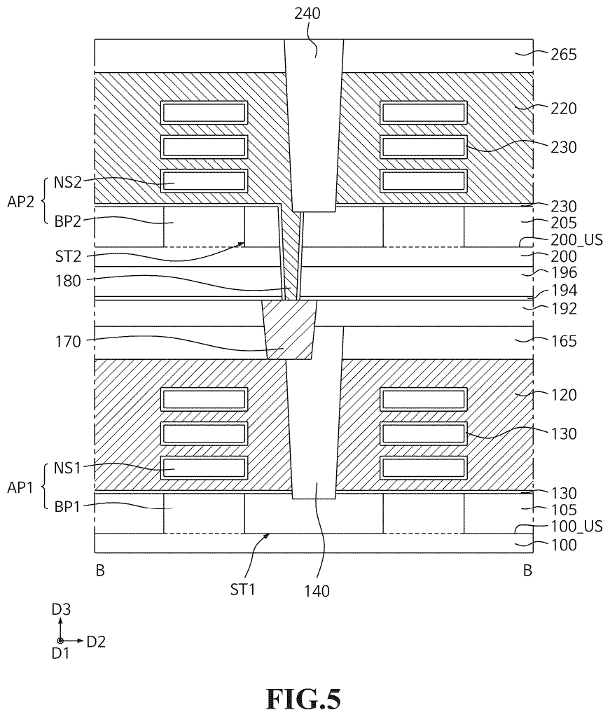

FIG. 5 is a diagram provided to explain a semiconductor device according to some embodiments. For convenience of description, different configurations from those described in FIGS. 1 to 4 will be mainly described.

Referring to FIG. 5, in a semiconductor device according to some embodiments, the connection via 180 may include the same material as the second gate electrode 220. A boundary surface between the connection via 180 and the second gate electrode 220 may not be distinguished.

In some embodiments, the connection via 180 and the second gate electrode 220 may be formed at once. In other words, the connection via 180 and the second gate electrode 220 may be formed by the same process.

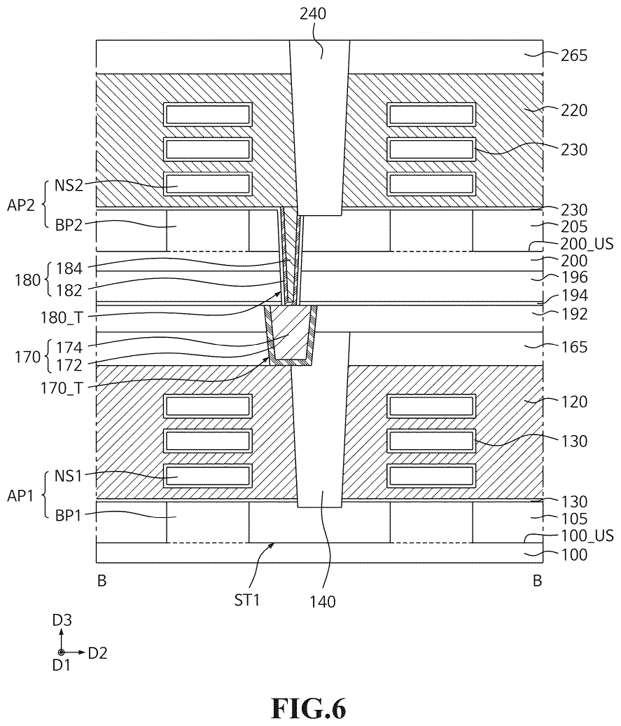

FIG. 6 is a diagram provided to explain a semiconductor device according to some embodiments. For convenience of description, different configurations from those described in FIGS. 1 to 4 will be mainly described.

Referring to FIG. 6, in a semiconductor device according to some embodiments, the gate contact 170 and the connection via 180 may include a plurality of layers.

The gate contact 170 may include a first barrier film 172 and a first filling film 174. The first barrier film 172 may be disposed along a gate contact trench 170_T. The first barrier film 172 may be in contact with each of the second interlayer insulating film 192, the first gate capping pattern 165, the first gate electrode 120, and the first gate isolation structure 140. The first filling film 174 may be disposed on the first barrier film 172. The first filling film 174 may fill the gate contact trench 170_T.

The connection via 180 may include a second barrier film 182 and a second filling film 184. The second barrier film 182 may be disposed along a connection via trench 180_T. The second barrier film 182 may be disposed along the second gate insulating film 230 disposed on the connection via trench 180_T. The second filling film 184 may be disposed on the second barrier film 182. The second filling film 184 may fill the connection via trench 180_T.

In some embodiments, the second barrier film 182 may be disposed between the second filling film 184 and the first filling film 174. A portion of the second barrier film 182 may be in contact with the first filling film 174. However, embodiments are not limited to the above. For example, the second barrier film 182 may not be disposed between the second filling film 184 and the first filling film 174, and the second filling film 184 may be in contact with the first filling film 174.

Each of the first barrier film 172 and the second barrier film 182 may include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbon nitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), or a 2D material. Each of the first filling film 174 and the second filling film 184 may include at least one of, for example, aluminum (Al), copper (Cu), tungsten (W), cobalt (Co), ruthenium (Ru), silver (Ag), gold (Au), manganese (Mn), or molybdenum (Mo).

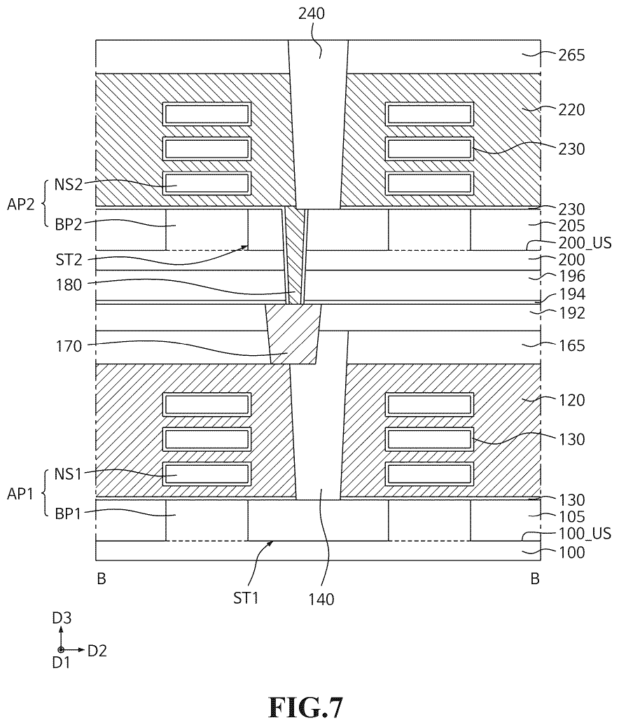

FIG. 7 is a diagram provided to explain a semiconductor device according to some embodiments. For convenience of description, different configurations from those described in FIGS. 1 to 4 will be mainly described.

Referring to FIG. 7, in a semiconductor device according to some embodiments, the first gate isolation structure 140 may be disposed on the first field insulating film 105.

The first gate isolation structure 140 may penetrate or extend into the first gate capping pattern 165, the first gate electrode 120, and the first gate insulating film 130. The lower surface of the first gate isolation structure 140 may be disposed on the upper surface of the first field insulating film 105. The first gate isolation structure 140 may not penetrate or may not extend into the first field insulating film 105, according to some embodiments.

The second gate isolation structure 240 may penetrate or extend into the second gate capping pattern 265, the second gate electrode 220, and the second gate insulating film 230. The lower surface of the second gate isolation structure 240 may be disposed on the upper surface of the second field insulating film 205. The second gate isolation structure 240 may not penetrate or may not extend into the second field insulating film 205. The lower surface of the second gate isolation structure 240 may be in contact with the connection via 180.

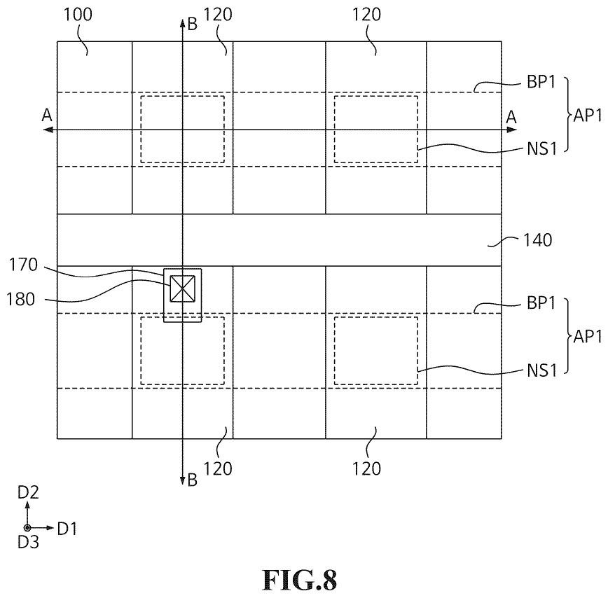

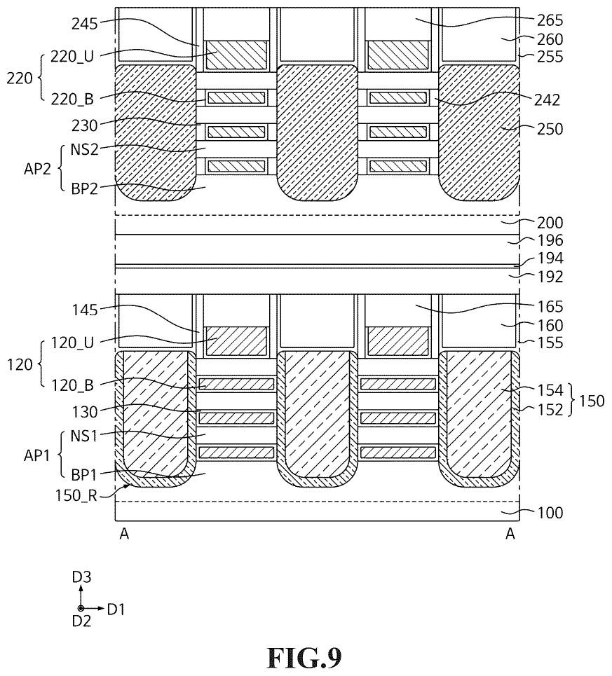

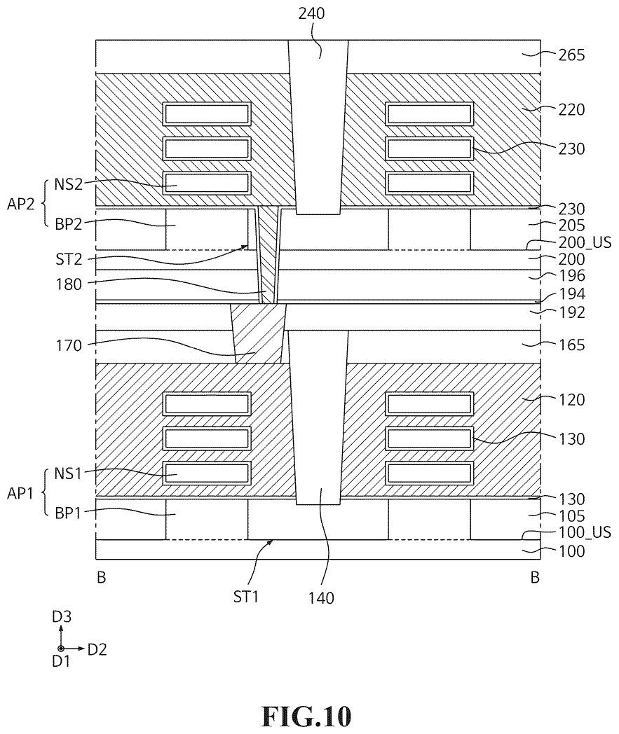

FIGS. 8 to 10 are diagrams provided to explain a semiconductor device according to some embodiments. For reference, FIG. 8 is a plan view provided to explain a semiconductor device according to some embodiments. FIG. 9 is a cross-sectional view taken along line A-A of FIG. 8. FIG. 10 is a cross-sectional view taken along line B-B of FIG. 8. For convenience of description, different configurations from those described in FIGS. 1 to 4 will be mainly described.

The first active pattern AP1 may be disposed on the first substrate 100. The second active pattern AP2 may be disposed on the second substrate 200. The first active pattern AP1 may be a region in which a PMOS is formed, and the second active pattern AP2 may be a region in which an NMOS is formed.

The first source/drain pattern 150 may be disposed in a source/drain recess 150_R. The first source/drain pattern 150 may include a first semiconductor layer 152 and a second semiconductor layer 154.

The first semiconductor layer 152 may extend along a side surface and a bottom surface of the source/drain recess 150_R. The first semiconductor layer 152 may be in contact with the first lower pattern BP1, the first gate insulating film 130, the first gate spacer 145, and the first sheet pattern NS1. The second semiconductor layer 154 may be disposed on the first semiconductor layer 152. The second semiconductor layer 154 may fill the source/drain recess 150_R.

Each of the first semiconductor layer 152 and the second semiconductor layer 154 may include silicon-germanium. The germanium fraction of the first semiconductor layer 152 may be different from that of the second semiconductor layer 154. For example, the germanium fraction of the first semiconductor layer 152 may be less than that of the second semiconductor layer 154.

In some embodiments, each of the first semiconductor layer 152 and the second semiconductor layer 154 may further include a doped P-type impurity. For example, the P-type impurity may be boron (B), but is not limited thereto.

An inner gate spacer 242 may be disposed between the second lower gate electrode 220_B and the second source/drain pattern 250. The second source/drain pattern 250 and the second gate insulating film 230 may be disposed on both side surfaces of the inner gate spacer 242. The second gate electrode 220 may be spaced apart from the second source/drain pattern 250 by the inner gate spacer 242.

For example, the inner gate spacer 242 may include at least one of silicon oxide (SiO), silicon nitride oxide (SiON), silicon boron nitride (SiBN), silicon oxycarbonitride (SiOCN), and/or silicon nitride (SiN).

Although it is illustrated that the inner gate spacer 242 is disposed between the second source/drain pattern 250 and the second gate electrode 220, embodiments are not limited thereto. For example, the inner gate spacer may be disposed between the first source/drain pattern 150 and the first gate electrode 120.

The gate contact 170 may be disposed on the first gate electrode 120. The gate contact 170 may be connected to the first gate electrode 120. The gate contact 170 may be disposed to be spaced apart from each other in the second direction D2 of the first gate isolation structure 140. In other words, the gate contact 170 may not overlap the first gate isolation structure 140 in the third direction D3.

The connection via 180 may be disposed between the gate contact 170 and the second gate electrode 220. The connection via 180 may be disposed to be spaced apart from the second gate isolation structure 240 in the second direction D2. In other words, the connection via 180 may not overlap the second gate isolation structure 240 in the third direction D3.

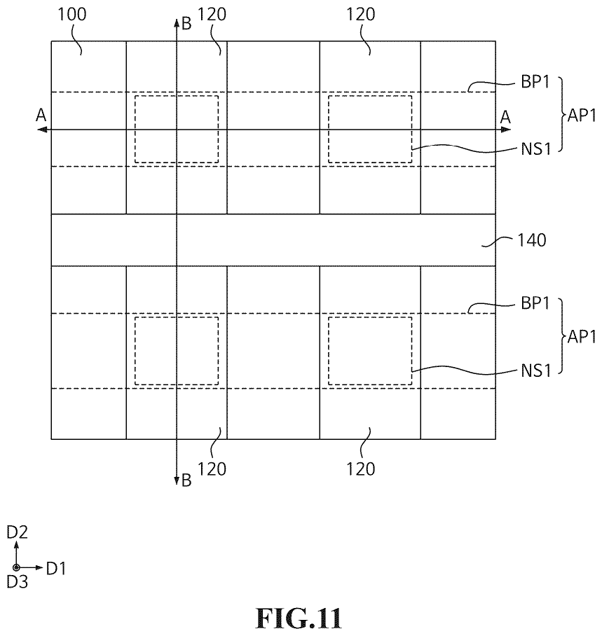

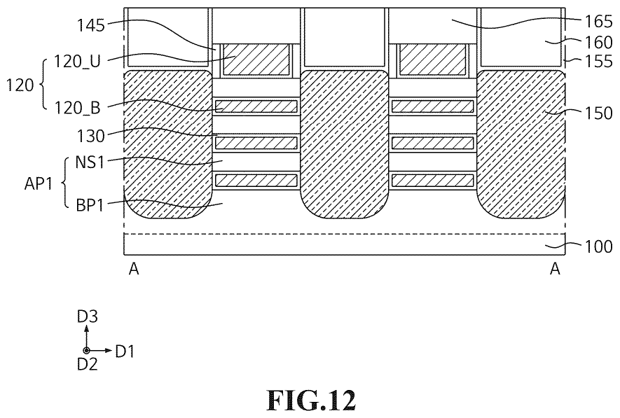

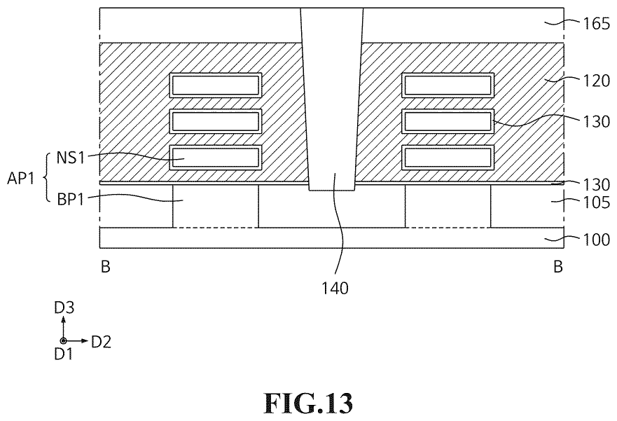

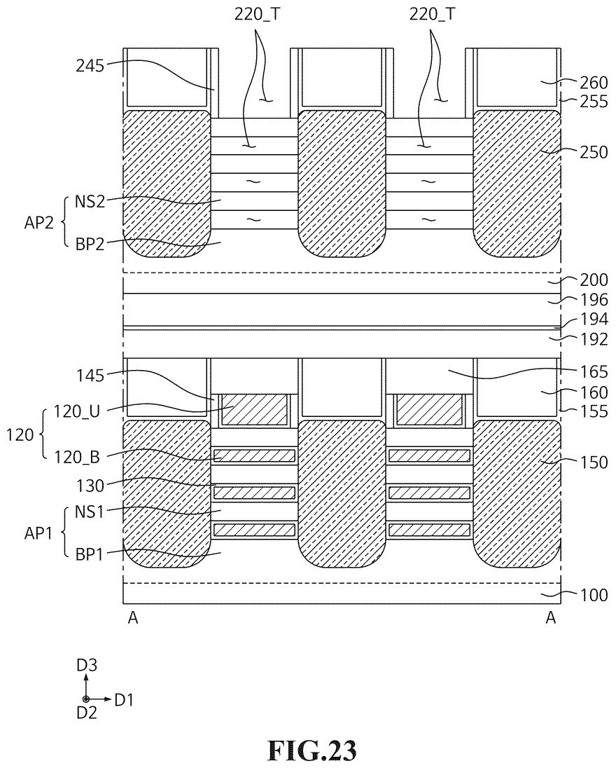

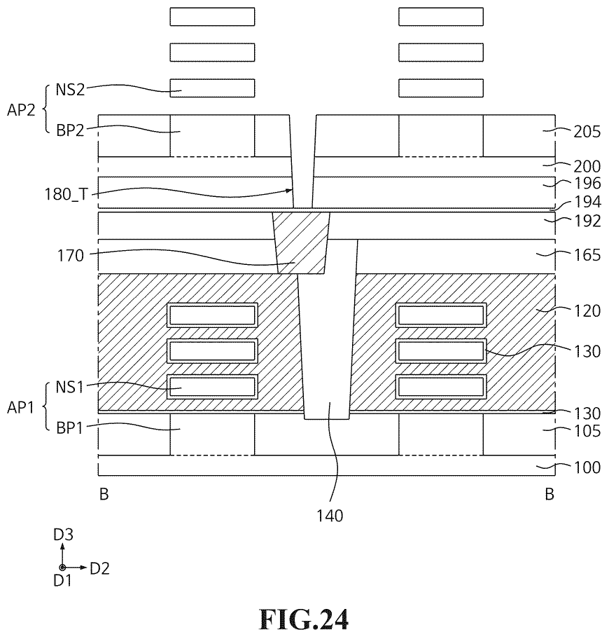

FIGS. 11 to 28 are diagrams illustrating intermediate stages, which are provided to explain a method for manufacturing a semiconductor device according to some embodiments. FIG. 11 is a plan view illustrating a method for manufacturing a semiconductor device according to some embodiments. FIGS. 12, 15, 17, 19, 21, 23, 25 and 27 are cross-sectional views taken along line A-A of FIG. 11. FIGS. 13, 14, 16, 18, 20, 22, 24, 26, and 28 are cross-sectional views taken along line B-B of FIG. 11. In addition, description of the configurations of FIGS. 11 to 28 overlap the above description of the configurations in FIGS. 1 to 10 and may be omitted.

Referring to FIGS. 11 to 13, a method for manufacturing a semiconductor device according to some embodiments may include forming the first active pattern AP1, the first gate electrode 120, the first gate insulating film 130, the first source/drain pattern 150, the first etching stop film 155, the first interlayer insulating film 160, and the first gate capping pattern 165 on the first substrate 100.

The first gate isolation structure 140 penetrating or extending into the first gate capping pattern 165 and the first gate electrode 120 may be formed. The first gate isolation structure 140 may extend in the first and third directions D1 and D3. The first gate electrodes 120 disposed on both sides of the first gate isolation structure 140 may be insulated from each other.

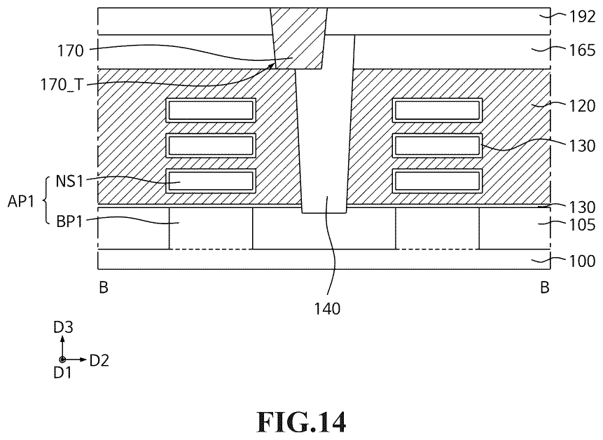

Referring to FIG. 14, the gate contact 170 may be formed on the first gate electrode 120.

In detail, the second interlayer insulating film 192 may be formed on the first gate capping pattern 165 and the first gate isolation structure 140. The gate contact trench 170_T may be formed by etching the second interlayer insulating film 192 and the first gate capping pattern 165. The gate contact trench 170_T may expose a portion of the upper surface of the first gate electrode 120.

In some embodiments, the gate contact trench 170_T may overlap the first gate isolation structure 140 in the third direction D3. The gate contact trench 170_T may expose a portion of the first gate isolation structure 140.

The gate contact 170 may be formed by partially or completely filling the gate contact trench 170_T with a conductive material.

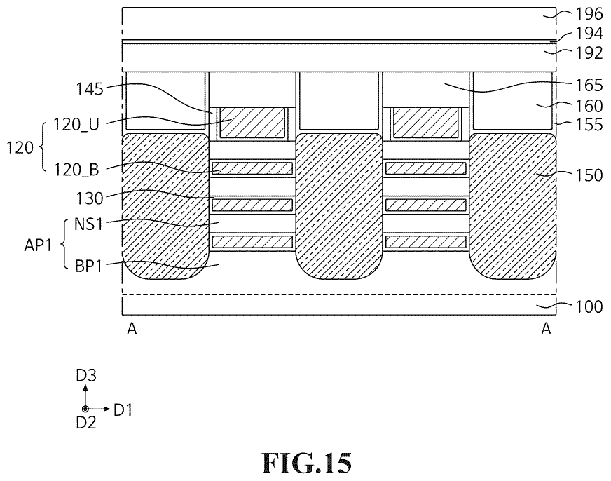

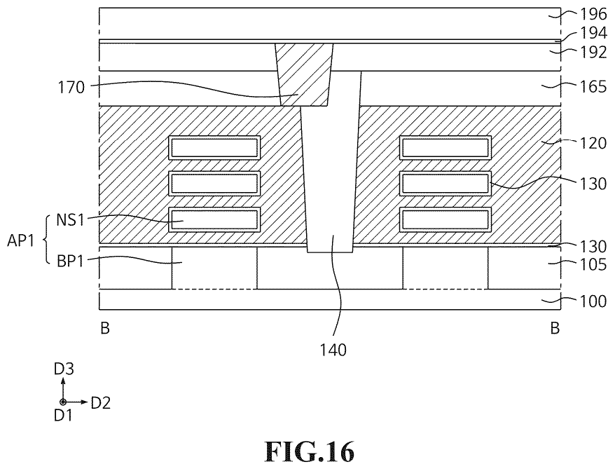

Referring to FIGS. 15 and 16, the second etching stop film 194 and the bonding layer 196 may be formed on the second interlayer insulating film 192.

The second etching stop film 194 may be formed on the second interlayer insulating film 192 and the gate contact 170. The bonding layer 196 may be formed on the second etching stop film 194. That is, the second etching stop film 194 and the bonding layer 196 may be sequentially stacked on the second interlayer insulating film 192.

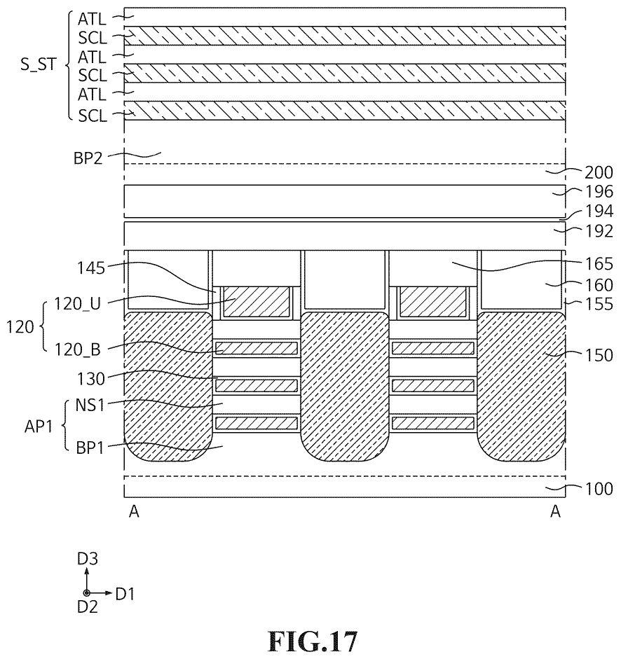

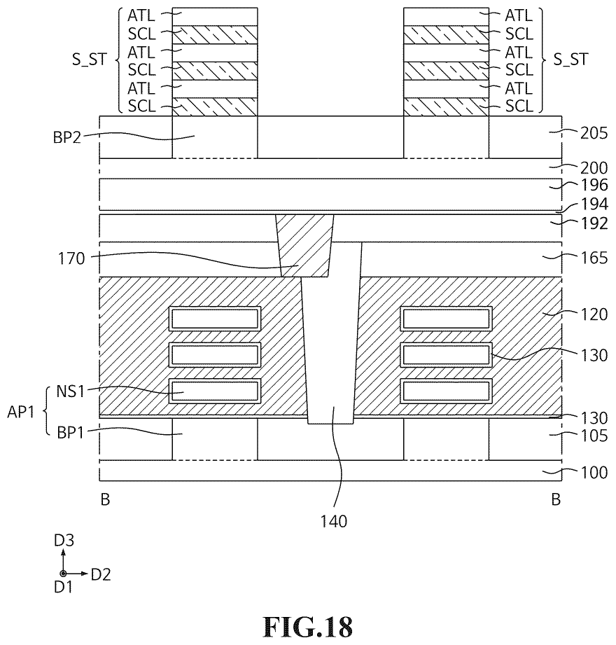

Referring to FIGS. 17 and 18, the second substrate 200, the second lower pattern BP2, and the stack structure S_ST may be formed on the bonding layer 196.

In some embodiments, the second substrate 200, the second lower pattern BP2, and the stack structure S_ST may be formed and provided on a separate wafer. For example, the stack structure S_ST, the second lower pattern BP2, and the second substrate 200 may be formed on a carrier wafer. The carrier wafer may be moved so that the second substrate 200 may be disposed on the bonding layer 196, and the second substrate 200 and the bonding layer 196 may be combined. However, embodiments are not limited to the above. For example, the second substrate 200, the second lower pattern BP1, and the stack structure S_ST may be sequentially stacked on the bonding layer 196.

A portion of the stack structure S_ST may be etched to form a second device isolation trench. The second field insulating film 205 may be formed on the second device isolation trench.

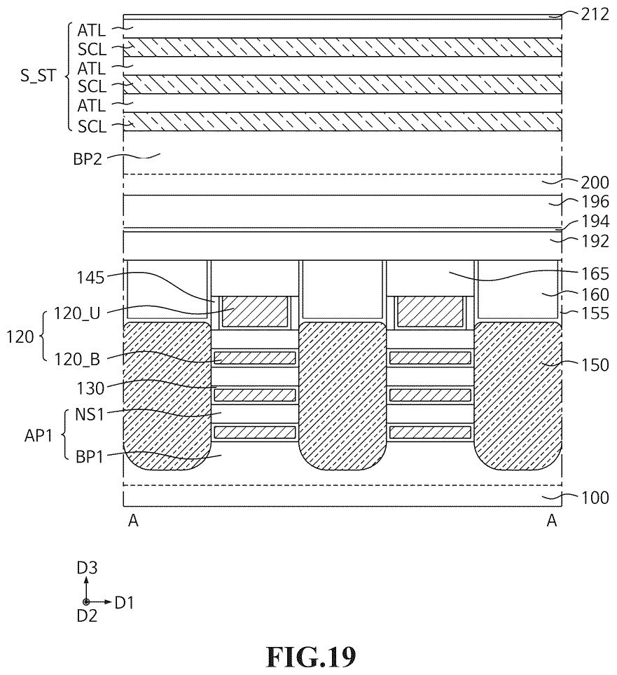

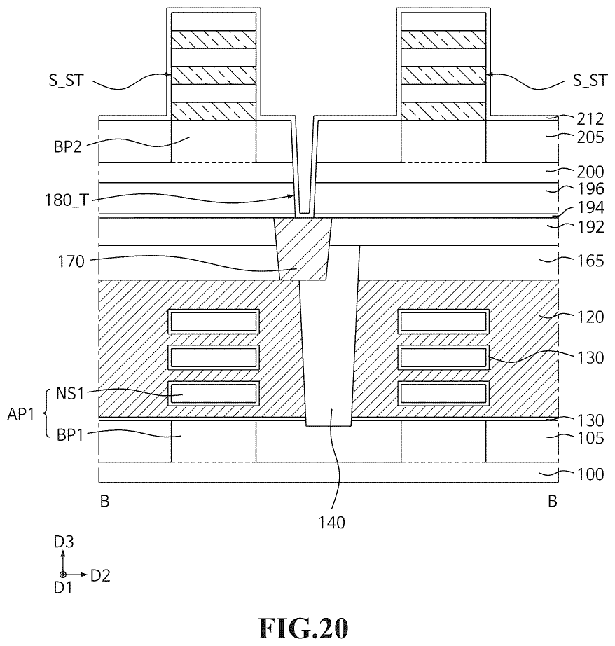

Referring to FIGS. 19 and 20, the connection via trench 180_T may be formed on the second field insulating film 205, and a protection insulating film 212 may be formed on the stack structure S_ST, the second field insulating film 205, and the connection via trench 180_T.

Specifically, a portion of the second field insulating film 205 may be removed to form the connection via trench 180_T. The connection via trench 180_T may penetrate or extending into the second field insulating film 205, the second substrate 200, and the bonding layer 196. The connection via trench 180_T may expose a portion of an upper surface of the second etching stop film 194. The connection via trench 180_T may overlap the gate contact 170 in the third direction D3.

The protection insulating film 212 may be formed on the stack structure S_ST, the second field insulating film 205, and the connection via trench 180_T. The protection insulating film 212 may cover or overlap an upper surface of the stack structure S_ST. The protection insulating film 212 may cover or overlap a side surface and a bottom surface of the connection via trench 180_T.

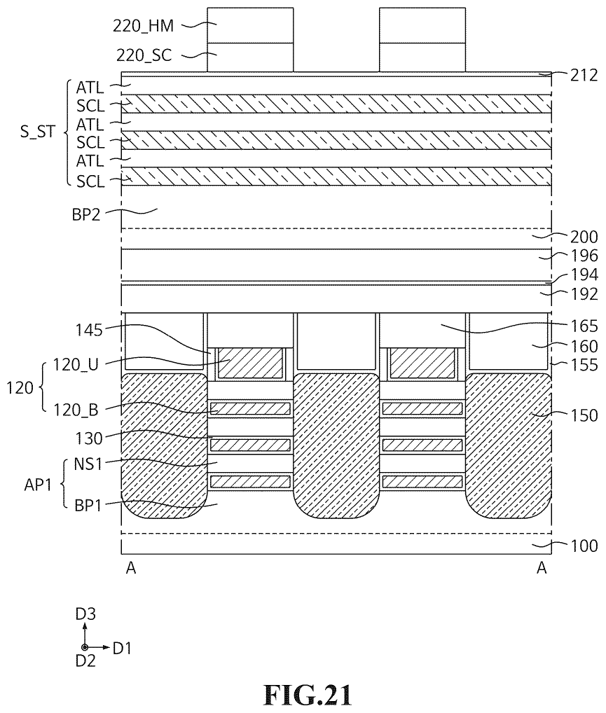

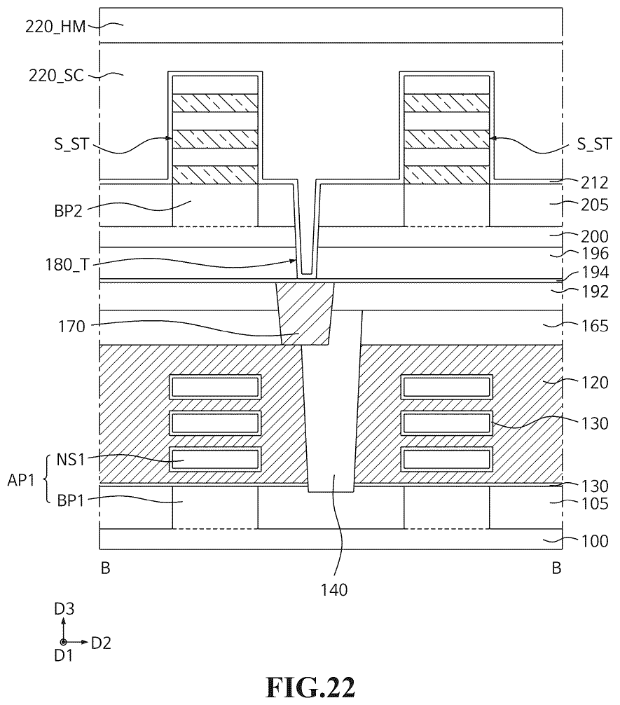

Referring to FIGS. 21 and 22, a gate sacrificial pattern 220_SC and a hard mask pattern 220_HM may be formed on the protection insulating film 212.

Specifically, polysilicon may be formed on the stacked structure S_ST. In addition, using the hard mask pattern 220_HM as a mask, polysilicon may be patterned to form the gate sacrificial pattern 220_SC. The hard mask pattern 220_HM on the gate sacrificial pattern 220_SC may not be removed. The gate sacrificial pattern 220_SC may extend in the second direction D2. The gate sacrificial pattern 220_SC may intersect the stack structure S_ST. The gate sacrificial pattern 220_SC may cover or overlap a portion of the protection insulating film 212.

Referring to FIGS. 21 to 24, the second source/drain pattern 250, the third etching stop film 255, and the second interlayer insulating film 260 may be formed on the second substrate 200.

Specifically, the stack structure S_ST may be patterned by using the hard mask pattern 220_HM as an etching mask. A portion of the stack structure S_ST may be removed to form an upper source/drain recess, and the second source/drain pattern 250 may be formed on the upper source/drain recess. The third etching stop film 255 and the second interlayer insulating film 260 may be formed on the second source/drain pattern 250.

The protection insulating film 212 and the hard mask pattern 220_HM may be removed to expose the gate sacrificial pattern 220_SC. The gate sacrificial pattern 220_SC and the sacrificial semiconductor layer SCL may be removed to form a gate electrode trench 220_T. Further, the sacrificial semiconductor layer SCL may be removed to form the second active pattern AP2.

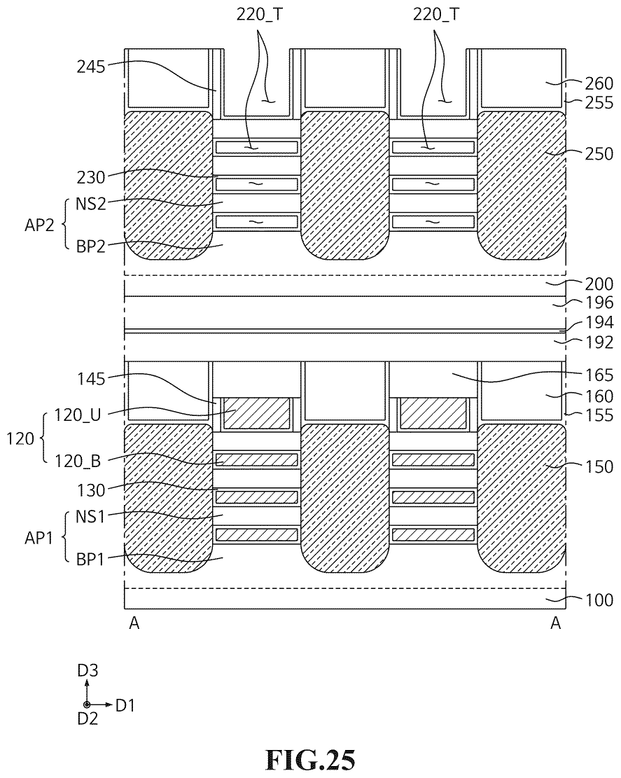

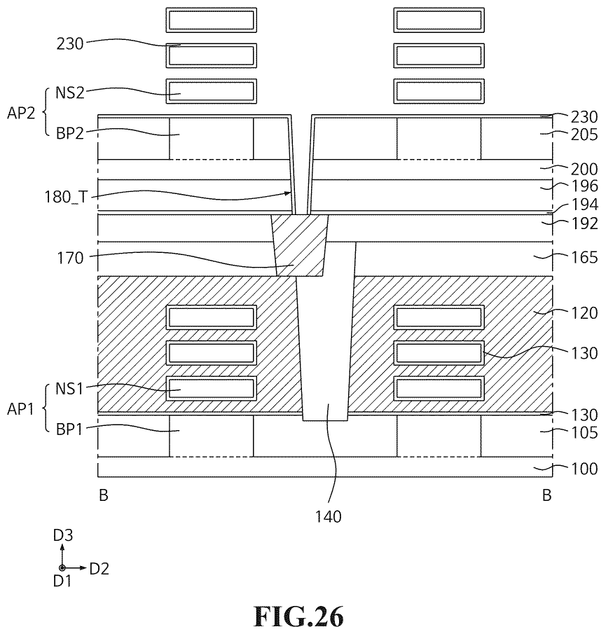

Referring to FIGS. 25 and 26, the second gate insulating film 230 may be formed inside the gate electrode trench 220_T, and on the second sheet pattern NS2, the second gate spacer 245, and the connection via trench 180_T.

Specifically, the second gate insulating film 230 may be formed along a sidewall and the bottom surface of the connection via trench 180_T. For example, the second gate insulating film 230 may be formed by using the atomic layer deposition (ALD) process. The second gate insulating film 230 disposed on the bottom surface of the connection via trench 180_T may be removed by an etching process. A portion of the second gate insulating film 230 and the second etching stop film 194 may be removed to increase the depth of the connection via trench 180_T. As a result, the connection via trench 180_T may expose the upper surface of the gate contact 170.

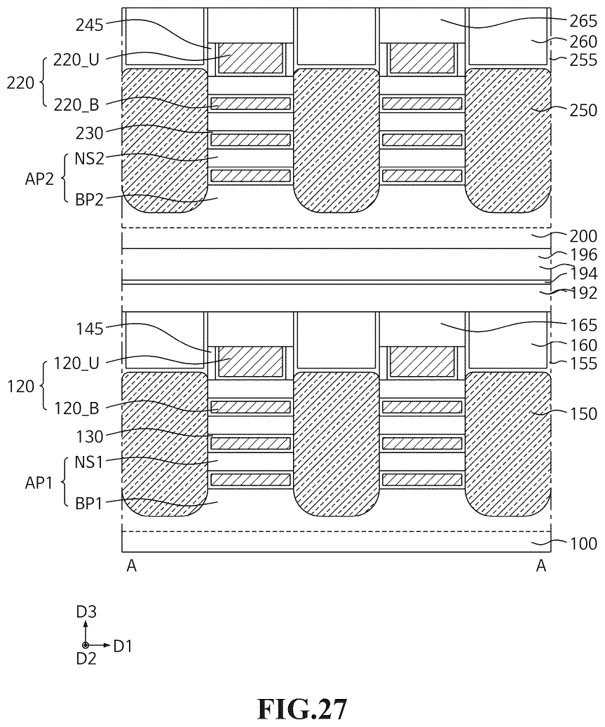

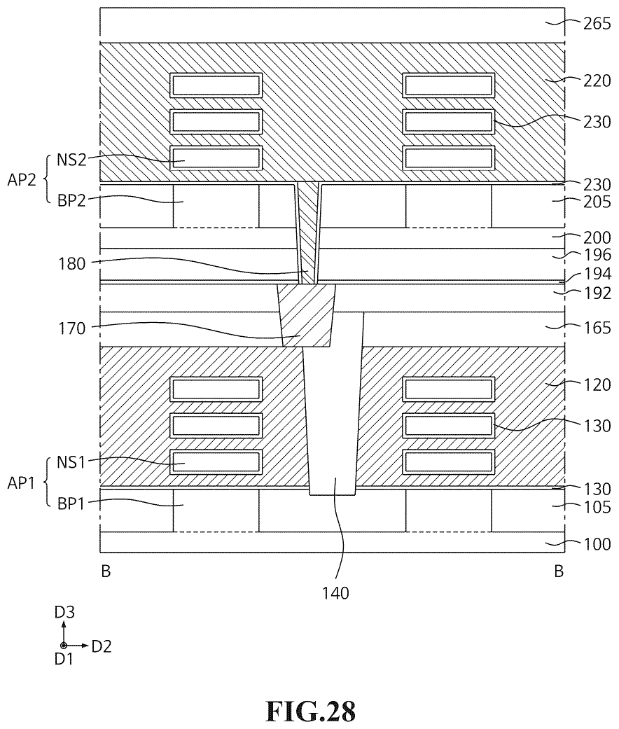

Referring to FIGS. 27 and 28, the connection via 180, the second gate electrode 220, and the second gate capping pattern 265 may be formed.

Specifically, the connection via 180 connected to the gate contact 170 may be formed. The second gate electrode 220 may be formed on the connection via 180. The connection via 180 may electrically connect the second gate electrode 220 and the gate contact 170. The second gate electrode 220 may surround or extend around the second sheet pattern NS2. The second gate capping pattern 265 may be formed on the second gate electrode 220.

In the process of forming the wiring structure for electrically connecting the first gate electrode 120 and the second gate electrode 220, electrical characteristics of the semiconductor device may deteriorate. For example, in the process of forming a through via that penetrates or extends into the second gate electrode 220 and is connected to the first gate electrode 120, the second active pattern AP2 may be damaged and the electrical characteristics of the semiconductor device may deteriorate.

According to some embodiments, the semiconductor device includes the connection via 180 formed on the gate contact 170, and the second gate electrode 220 formed on the connection via 180. The second active pattern AP2 is not damaged in the process of forming the connection via 180, and thus, electrical characteristics and reliability of the semiconductor device may be improved.

Referring to FIG. 3, the second gate isolation structure 240 penetrating or extending into the second gate electrode 220 may be further formed.

Although certain embodiments of the present disclosure have been described with reference to the accompanying drawings, those of ordinary skill in the art to which the present disclosure pertains will understand that the present disclosure may be implemented in other specific forms without changing its technical idea or features. Therefore, it should be understood that the embodiments described above are illustrative and non-limiting in all respects.

1. A semiconductor device, comprising:
a first substrate;
a first active pattern on the first substrate and extending in a first direction;
a first gate electrode on the first active pattern and extending in a second direction different from the first direction;
a gate capping pattern on the first gate electrode;
a gate contact extending into the gate capping pattern and electrically connected to the first gate electrode;
a bonding layer on the gate capping pattern;
a second substrate on the bonding layer;
a second active pattern on the second substrate and extending in the first direction, wherein the second active pattern comprises a lower pattern and a sheet pattern on the lower pattern;
a second gate electrode on the second active pattern and extending in the second direction; and
a connection via on the gate contact and electrically connected to each of the gate contact and the second gate electrode,
wherein the connection via extends into the second substrate.

2. The semiconductor device according to claim 1, wherein the connection via is spaced apart from the lower pattern in the second direction.

3. The semiconductor device according to claim 1, wherein the connection via does not overlap the sheet pattern in a third direction perpendicular to an upper surface of the second substrate.

4. The semiconductor device according to claim 1, further comprising:
an interlayer insulating film between the bonding layer and the gate capping pattern,
wherein the gate contact extends into the interlayer insulating film.

5. The semiconductor device according to claim 4, further comprising:
an etching stop film between the interlayer insulating film and the bonding layer,
wherein the connection via extends into the etching stop film.

6. The semiconductor device according to claim 1, further comprising:
a device isolation trench defined by an upper surface of the second substrate and a side surface of the lower pattern,
wherein a portion of the connection via is in the device isolation trench.

7. The semiconductor device according to claim 6, further comprising:
a device isolation film on the device isolation trench,
wherein the device isolation film surrounds a portion of the connection via.

8. The semiconductor device according to claim 1, further comprising:
a gate insulating film between the second active pattern and the second gate electrode,
wherein a portion of the gate insulating film is on a side surface of the connection via.

9. The semiconductor device according to claim 1, wherein the second gate electrode and the connection via comprise a same material.

10. The semiconductor device according to claim 1, wherein the gate contact comprises a barrier layer and a filling layer on the barrier layer.

11. The semiconductor device according to claim 1, further comprising:
a first gate isolation structure on a sidewall of the first gate electrode and extending in the first direction,
wherein a portion of the gate contact is in contact with the first gate isolation structure.

12. The semiconductor device according to claim 1, wherein the first gate electrode and the second gate electrode comprise different materials.

13. A semiconductor device, comprising:
a first substrate;
a first active pattern on the first substrate and extending in a first direction;
a first gate electrode on the first active pattern and extending in a second direction different from the first direction;
a first gate isolation structure on a sidewall of the first gate electrode and extending in the first direction;
a gate contact on the first gate electrode;
a second substrate on the gate contact;
a second active pattern on the second substrate and extending in the first direction, wherein the second active pattern comprises a lower pattern and a sheet pattern on the lower pattern;
a second gate electrode on the second active pattern and extending in the second direction;
a connection via on the gate contact and electrically connected to each of the gate contact and the second gate electrode; and
a second gate isolation structure on a sidewall of the second gate electrode and extending in the first direction,
wherein the connection via is spaced apart from the lower pattern in the second direction.

14. The semiconductor device according to claim 13, wherein a distance from an upper surface of the second substrate to a lower surface of the second gate isolation structure is less than a distance from the upper surface of the second substrate to an upper surface of the connection via.

15. The semiconductor device according to claim 13, wherein a portion of the gate contact overlaps the first gate isolation structure in a third direction, and
wherein the third direction is perpendicular to an upper surface of the second substrate.

16. The semiconductor device according to claim 13, further comprising:
a gate insulating film between the second active pattern and the second gate electrode,
wherein a portion of the gate insulating film is on a side surface of the connection via.

17. The semiconductor device according to claim 13, wherein the gate contact is spaced apart from the first gate isolation structure in the second direction, and
wherein the connection via is spaced apart from the second gate isolation structure in the second direction.

18. The semiconductor device according to claim 13, further comprising:
a first source/drain pattern on at least one side of the first gate electrode; and
a second source/drain pattern on at least one side of the second gate electrode,
wherein the first source/drain pattern and the second source/drain pattern include different conductivity types.

19. The semiconductor device according to claim 18, further comprising:
an inner gate spacer between the second source/drain pattern and the second gate electrode.

20. A semiconductor device, comprising:
a first substrate;
a first active pattern on the first substrate and extending in a first direction, wherein the first active pattern comprises a first lower pattern and a first sheet pattern on the first lower pattern;
a first gate electrode on the first active pattern and extending in a second direction different from the first direction;
a gate capping pattern on the first gate electrode;
a first gate isolation structure that extends into the gate capping pattern and the first gate electrode, and extends in the first direction;
an interlayer insulating film, a contact etching stop film, and a bonding layer on the gate capping pattern;
a gate contact on the first gate electrode and extending into the gate capping pattern and the interlayer insulating film;
a second substrate on the bonding layer;
a second active pattern on the second substrate and extending in the first direction, wherein the second active pattern comprises a second lower pattern and a second sheet pattern on the second lower pattern;
a second gate electrode on the second active pattern and extending in the second direction;
a connection via on the gate contact and electrically connected to each of the gate contact and the second gate electrode; and
a second gate isolation structure on a sidewall of the second gate electrode and extending in the first direction,
wherein the connection via extends into the second substrate, and the connection via is spaced apart from the second lower pattern in the second direction.
